(19) United States
(12) Patent Application Publication
(10) Pub. No.: US 2024/0109092 A1
(43) Pub. Date: Apr. 4, 2024

(54) DEPOSITION APPARATUS INCLUDING MASK ASSEMBLY AND MASK ASSEMBLY MANUFACTURING METHOD

(71) Applicant: Samsung Display Co., LTD., Yongin-si (KR)

(72) Inventors: AREUM LEE, Yongin-si (KR); SUNGSOON IM, Yongin-si (KR); ARONG KIM, Yongin-si (KR); YOUNGMIN MOON, Yongin-si (KR); YOUNGHO PARK, Yongin-si (KR); HEEMIN PARK, Yongin-si (KR); JUNHO JO, Yongin-si (KR)

(21) Appl. No.: 18/227,206

(22) Filed: Jul. 27, 2023

(30) Foreign Application Priority Data
Oct. 4, 2022 (KR) 10-2022-0126414

(51) Int. Cl. B05B 12/24

(52) U.S. Cl. CPC B05B 12/24

(57) ABSTRACT

A mask assembly includes a frame including first to fourth lateral parts connected to define a frame opening, an open sheet including a body part in which sheet openings arranged in a first direction and a second direction are defined to overlap the frame opening and a connecting part protruding from the body part and at least partially overlapping the frame, and masks, each including a deposition part having deposition openings defined therein and coupling parts that protrude from the deposition part and that are spaced apart from each other with the deposition part therebetween. The connecting part includes a first connecting part and a second connecting part that overlap the frame and a third connecting part and a fourth connecting part that at least partially overlap the frame.

This application claims priority under 35 U.S.C. § 119 to Korean Patent Application No. 10-2022-0126414, filed on Oct. 4, 2022, and all the benefits accruing therefrom under 35 U.S.C. § 119, the content of which in its entirety is herein incorporated by reference.

### BACKGROUND

### 1. Field

Embodiments of the disclosure described herein relate to a mask assembly and a manufacturing method thereof, and more particularly, relate to a mask assembly having reduced deformation and a manufacturing method thereof.

### 2. Description of the Related Art

In general, a light-emitting element is disposed in each of pixels in a light-emitting display device. The light-emitting element includes an emissive pattern disposed between electrodes spaced apart from each other. The emissive pattern included in each of the pixels may be divided into a plurality of groups.

A mask assembly is used to deposit the pixels on a working substrate. Functional layers may be formed by depositing a deposition material on the working substrate after placing the working substrate on the mask assembly.

### SUMMARY

Embodiments of the disclosure provide a mask assembly for minimizing heat generated in a deposition process or deformation occurring in a process of stretching sheets included in the mask assembly and a method for manufacturing the mask assembly.

In an embodiment of the disclosure, a mask assembly includes a frame, an open sheet, and masks. The frame includes a first lateral part and a second lateral part that extend in a first direction and that are spaced apart from each other in a second direction crossing the first direction and a third lateral part and a fourth lateral part that extend in the second direction and that are spaced apart from each other in the first direction and connected with the first lateral part and the second lateral part to define a frame opening. The open sheet includes a body part in which a plurality of sheet openings is defined and a connecting part that protrudes from the body part and at least partially overlaps the frame, and the plurality of sheet openings is arranged in the first direction and the second direction and overlap the frame opening. Each of the masks includes a deposition part in which deposition openings are defined to overlap a corresponding sheet opening among the plurality of sheet openings and coupling parts that protrude from the deposition part and that are spaced apart from each other with the deposition part therebetween. The connecting part includes a first connecting part that overlaps the first lateral part, a second connecting part that overlaps the second lateral part, third connecting parts that at least partially overlap the third lateral part, and fourth connecting parts that at least partially overlap the fourth lateral part.

In an embodiment, the third connecting parts may be spaced apart from each other in the second direction, the fourth connecting parts may be spaced apart from each other in the second direction, and the third connecting parts and the fourth connecting parts may not overlap the plurality of sheet openings when viewed in the first direction and the second direction.

In an embodiment, a first portion of the body part adjacent to the third lateral part may be spaced apart from the third lateral part by a predetermined gap, and a second portion of the body part adjacent to the fourth lateral part may be spaced apart from the fourth lateral part by a predetermined gap.

In an embodiment, one portion of each of the third connecting parts may overlap the frame opening, and a remaining portion of the third connecting part may overlap the third lateral part. One portion of each of the fourth connecting parts may overlap the frame opening, and a remaining portion of the fourth connecting part may overlap the fourth lateral part.

In an embodiment, the mask assembly may further include first welding protrusions formed on the remaining portion of the third connecting parts and second welding protrusions formed on the remaining portion of the fourth connecting parts.

In an embodiment, two third connecting parts adjacent to each other among the third connecting parts, the third lateral part, and the first portion of the body part may define an empty space extending in the second direction in a plan view, and two fourth connecting parts adjacent to each other among the fourth connecting parts, the fourth lateral part, and the second portion of the body part may define an empty space extending in the second direction in the plan view.

In an embodiment, the first connecting part may extend in the first direction and may overlap an entirety of the first lateral part, and the second connecting part may extend in the first direction and may overlap an entirety of the second lateral part.

In an embodiment, the coupling parts may extend in the first direction.

In an embodiment, the mask assembly may further include welding protrusions formed on the first connecting part and the second connecting part.

In an embodiment, widths of the first lateral part and the second lateral part in the first direction may be greater than widths of the third lateral part and the fourth lateral part in the second direction.

In an embodiment, widths of the first lateral part and the second lateral part in the first direction may be smaller than widths of the third lateral part and the fourth lateral part in the second direction.

In an embodiment, the frame, the open sheet, and the masks may include one of invar and stainless steel (“SUS”).

In an embodiment, each of the first connecting part and the second connecting part, when viewed in the second direction, may overlap sheet openings arranged in the first direction among the plurality of sheet openings.

In an embodiment, each of the masks may have a thickness of about micrometers (μm) to about 30 μm.

In an embodiment, the open sheet may have a thickness of about 50 μm to about 200 μm.

In an embodiment of the disclosure, a mask assembly manufacturing method includes providing a frame including first lateral parts that extend in a first direction and second lateral parts that extend in a second direction crossing the first direction and defining a frame opening with the first lateral parts, stretching an open sheet including a body part in which sheet openings are defined to overlap the frame opening and connecting parts that protrude from the body part, coupling the connecting parts to the frame through a first welding process, stretching a mask including a deposition part in which deposition openings are defined to overlap one sheet opening among the sheet openings and coupling parts that protrude from the deposition part in the second direction and extend in the first direction, and coupling the coupling parts to the open sheet through a second welding process. A connecting part having a relatively large area coupled with the frame among the connecting parts extends in the first direction, and the stretching the mask includes stretching the coupling parts in the second direction.

In an embodiment, each of the coupling parts may include a first portion that protrudes from the deposition part and a second portion that protrudes from the first portion, and the stretching the mask may include stretching the second portion in a direction in which the second portion protrudes.

In an embodiment, the mask assembly manufacturing method may further include removing the second portions from the mask.

In an embodiment, an arrangement direction of welding protrusions formed on the connecting part having the relatively large area coupled with the frame among the connecting parts may be the same as an arrangement direction of welding protrusions formed on the coupling parts.

In an embodiment, a portion of the body part adjacent to a connecting part having a relatively small area coupled with the frame among the connecting parts may be spaced apart from the frame by a predetermined gap.

In an embodiment of the disclosure, a mask assembly includes a frame, an open, and masks. The frame includes a first lateral part and a second lateral part that extend in a first direction and that are spaced apart from each other in a second direction crossing the first direction and a third lateral part and a fourth lateral part that extend in the second direction and that are spaced apart from each other in the first direction and connected with the first lateral part and the second lateral part to define a frame opening. The open sheet includes first sticks that extend in the first direction and that are spaced apart from each other in the second direction and second sticks that extend in the second direction and that are spaced apart from each other in the first direction, and the second sticks intersect the first sticks to define a plurality of sheet openings. Each of the masks includes a deposition part in which deposition openings are defined to overlap a corresponding sheet opening among the plurality of sheet openings and coupling parts that protrude from the deposition part and that are spaced apart from each other with the deposition part therebetween. Stick recesses are defined in a thickness direction on sticks disposed away from the frame among the first sticks and the second sticks, and portions of sticks disposed adjacent to the frame are inserted into the corresponding stick recesses.

In an embodiment, each of the first sticks may include first connecting portions coupled with the first lateral part and the second lateral part and a first central portion that is disposed between the first connecting portions and that overlaps the frame opening, and each of the second sticks may include second connecting portions coupled with the third lateral part and the fourth lateral part and a second central portion that is disposed between the second connecting portions and that intersects the first central portions to define the plurality of sheet openings.

In an embodiment, widths of the first sticks in the first direction may be greater than widths of the second sticks in the second direction. The first sticks may be disposed farther away from the frame than the second sticks. A first central portion of each of first sticks adjacent to the first lateral part and the second lateral part among the first sticks may be coupled with the first lateral part and the second lateral part.

In an embodiment, each of the coupling parts may be coupled to a corresponding first central portion among the first central portions.

In an embodiment, widths of the first sticks in the first direction may be greater than widths of the second sticks in the second direction. The second sticks may be disposed farther away from the frame than the first sticks. The second central portion of each of second sticks adjacent to the third lateral part and the fourth lateral part among the second sticks may be coupled with the third lateral part and the fourth lateral part.

In an embodiment, each of the coupling parts may be coupled to a corresponding second central portion among the second central portions.

### BRIEF DESCRIPTION OF THE DRAWINGS

The above and other embodiments, advantages and features of the disclosure will become apparent by describing in detail embodiments thereof with reference to the accompanying drawings.

FIG. 1 is a cross-sectional view of an embodiment of a deposition apparatus according to the disclosure.

FIG. 2 is a plan view of an embodiment of a mask assembly according to the disclosure.

FIG. 3 is an exploded perspective view of an embodiment of the mask assembly according to the disclosure.

FIG. 4 is a plan view of an embodiment of a mask assembly according to the disclosure.

FIG. 5 is an exploded perspective view of an embodiment of the mask assembly according to the disclosure.

FIG. 6A is a perspective view illustrating an embodiment of a mask assembly manufacturing method according to the disclosure.

FIG. 6B is a plan view illustrating an embodiment of the mask assembly manufacturing method according to the disclosure.

FIG. 6C is a plan view illustrating an embodiment of the mask assembly manufacturing method according to the disclosure.

FIG. 6D is a plan view illustrating an embodiment of the mask assembly manufacturing method according to the disclosure.

FIG. 6E is a plan view illustrating an embodiment of the mask assembly manufacturing method according to the disclosure.

FIG. 6F is a plan view illustrating an embodiment of the mask assembly manufacturing method according to the disclosure.

FIG. 7 is a plan view of an embodiment of a mask assembly according to the disclosure.

FIG. 8 is an exploded perspective view of an embodiment of the mask assembly according to the disclosure.

FIG. 9 is a cross-sectional view taken along line I-I′ of FIG. 7.

FIG. 10 is a plan view of an embodiment of a mask assembly according to the disclosure.

FIG. 11 is an exploded perspective view of an embodiment of the mask assembly according to the disclosure.

FIG. 12 is a cross-sectional view of an embodiment of a display panel according to the disclosure.

### DETAILED DESCRIPTION

In this specification, when it is mentioned that a component (or, a region, a layer, a part, etc.) is referred to as being “on”, “connected to” or “coupled to” another component, this means that the component may be directly on, connected to, or coupled to the other component or a third component may be therebetween.

Identical reference numerals refer to identical components. Additionally, in the drawings, the thicknesses, proportions, and dimensions of components are exaggerated for effective description. As used herein, the term “and/or” includes all of one or more combinations defined by related components.

Terms such as first, second, and the like may be used to describe various components, but the components should not be limited by the terms. The terms may be used only for distinguishing one component from other components. For example, without departing the scope of the disclosure, a first component may be referred to as a second component, and similarly, the second component may also be referred to as the first component. The terms of a singular form may include plural forms unless otherwise specified.

In addition, terms such as “below”, “under”, “above”, and “over” are used to describe a relationship of components illustrated in the drawings. The terms are relative concepts and are described based on directions illustrated in the drawing.

It should be understood that terms such as “comprise”, “include”, and “have”, when used herein, specify the presence of stated features, numbers, steps, operations, components, parts, or combinations thereof, but do not preclude the presence or addition of one or more other features, numbers, steps, operations, components, parts, or combinations thereof.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). The term “about” can mean within one or more standard deviations, or within ±30%, 20%, 10%, 5% of the stated value, for example.

Unless otherwise defined, all terms used herein, including technical or scientific terms, have the same meanings as those generally understood by those skilled in the art to which the disclosure pertains. Such terms as those defined in a generally used dictionary are to be interpreted as having meanings equal to the contextual meanings in the relevant field of art, and are not to be interpreted as having ideal or excessively formal meanings unless clearly defined as having such in the application.

Hereinafter, embodiments of the disclosure will be described with reference to the accompanying drawings.

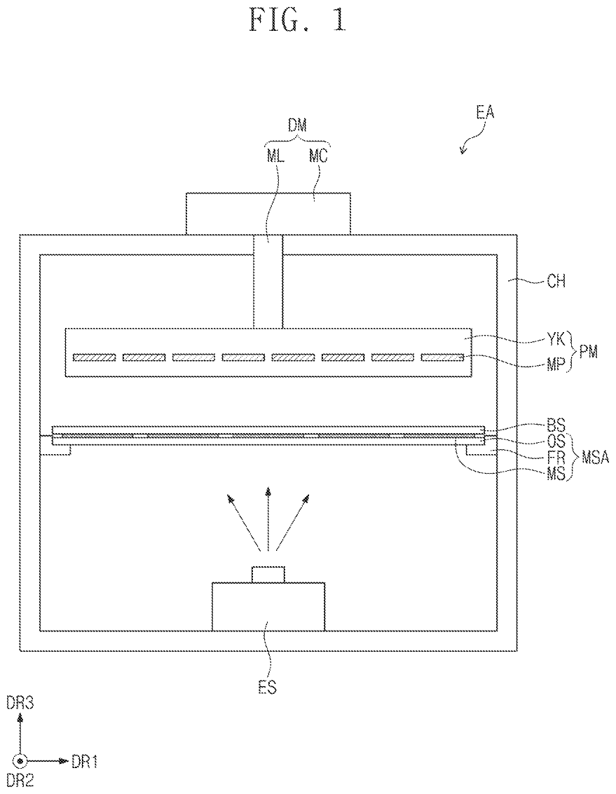

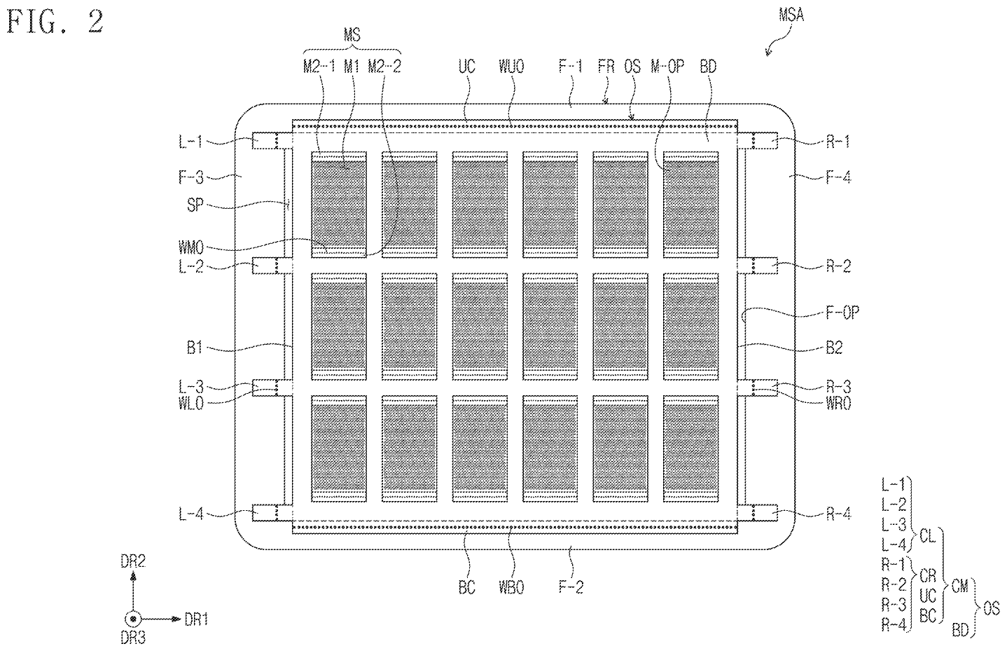

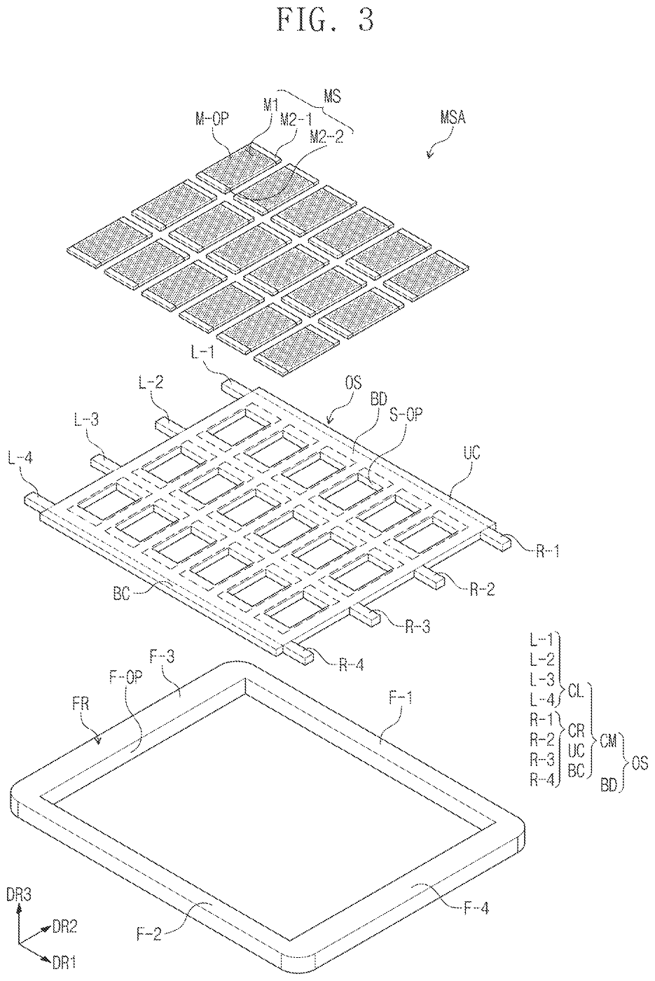

FIG. 1 is a cross-sectional view of an embodiment of a deposition apparatus according to the disclosure. FIG. 2 is a plan view of an embodiment of a mask assembly according to the disclosure. FIG. 3 is an exploded perspective view of an embodiment of the mask assembly according to the disclosure.

Referring to FIG. 1, the deposition apparatus EA according to the disclosure includes a chamber CH, a deposition source ES, the mask assembly MSA, a deposition substrate BS, a pressing unit PM, and a transport unit DM. The deposition apparatus EA may be an apparatus that deposits an organic material or a conductive material on the deposition substrate BS.

The chamber CH provides an inner space in which a deposition process is performed. The deposition source ES, the mask assembly MSA, the deposition substrate BS, the pressing unit PM, and a transport rod ML of the transport unit DM may be disposed in the inner space of the chamber CH.

The deposition source ES provide a deposition material to the deposition substrate BS. In an embodiment, the deposition source ES may evaporate a deposition material including one of an inorganic material and an organic material and may spray the evaporated deposition material toward the mask assembly MSA, for example. At this time, the deposition material may pass through the mask assembly MSA and may be deposited on the deposition substrate BS. In this case, the deposition source ES may be implemented by a method of evaporating the deposition material by heating the deposition material at relatively high temperature. In an embodiment, the deposition apparatus EA may further include a transport unit that moves the deposition source ES in a first direction DR1 and a second direction DR2.

The pressing unit PM may include a magnetic plate MP and a support plate YK. In an embodiment, the pressing unit PM may further include a cooling plate disposed between the deposition substrate BS and the support plate YK.

The magnetic plate MP may be disposed inside the support plate YK. The magnetic plate MP may attract masks MS by generating a magnetic force in a state in which the deposition substrate BS and the mask assembly MSA are brought into close contact with each other. The magnetic plate MP may prevent separation due to a difference in curvature between the deposition substrate BS and the masks MS, thereby preventing a shadowing phenomenon that is a deposition defect. The magnetic plate MP may be implemented with one of a permanent magnet and an electromagnet.

Accordingly, a coupling force between the deposition substrate BS and the mask assembly MSA may be increased. The positions, shapes, and number of magnetic plates MP are not limited to any particular embodiment as long as the magnetic plates MP are disposed on the mask assembly MSA to couple the masks MS included in the mask assembly MSA and the deposition substrate BS by a magnetic force.

The support plate YK may accommodate the magnetic plate MP. The support plate YK may be coupled with the transport unit DM and may bring the magnetic plate MP into close contact with the deposition substrate BS or may separate the magnetic plate MP from the deposition substrate BS.

The cooling plate may be disposed between the deposition substrate BS and the support plate YK. The cooling plate provides a function of cooling the deposition substrate BS or the masks MS to prevent the deposition substrate BS or the masks MS from being overheated in the deposition process. Accordingly, deformation of the deposition substrate BS may be prevented. A cooling line into which cooling water or cooled air is injected may be provided inside the cooling plate.

The transport unit DM is connected to the pressing unit PM. The transport unit DM may include the transport rod ML and a transport body part MC. The transport body part MC may transport the pressing unit PM in a third direction DR3, that is, in an up/down direction via the transport rod ML.

In an embodiment, the transport body part MC may be disposed outside the chamber CH, for example. The transport body part MC may be implemented with one of a cylinder and a motor. In an embodiment, in the case in which the transport body part MC is a cylinder, the transport rod ML may be a piston, for example. In the case in which the transport body part MC is a motor, the transport rod ML may be implemented with a ball screw shaft that is movable upward/downward as the motor rotates. However, the transport unit DM is not limited to any one device as long as the transport unit DM is capable of moving the pressing unit PM.

The mask assembly MSA may be disposed in the chamber CH and may support the deposition substrate BS. The mask assembly MSA may include a frame FR, an open sheet OS, and the plurality of masks MS. The frame FR, the open sheet OS, and the masks MS may include one of invar and stainless steel.

The frame FR may be disposed on a sidewall of the chamber CH and may support the open sheet OS to which the masks MS are coupled. A frame opening F-OP (refer to FIG. 2) may be defined in the frame FR. The shapes, positions, and number of frames FR are not limited to any particular embodiment as long as the frames FR support the open sheet OS.

Referring to FIGS. 2 and 3, the mask assembly MSA in an embodiment may include the frame FR, the open sheet OS, and the masks MS.

The open sheet OS may be disposed on the frame FR and may be coupled with the frame FR through a welding process. Welding protrusions WUO, WBO, WLO, and WRO formed in the welding process may be provided on portions of a connecting part CM of the open sheet OS that are coupled with the frame FR. The masks MS may be disposed on the open sheet OS and may be coupled with the open sheet OS through a welding process. Welding protrusions WMO formed in the welding process may be provided on coupling parts M2-1 and M2-2 of each of the masks MS. However, a coupling of the open sheet OS and the frame FR and a coupling of the masks MS and the open sheet OS are not limited to a welding process and may be performed through a separate structure or an adhesive. In this case, the welding protrusions may be omitted.

The frame FR may include first to fourth lateral parts F-1, F-2, F-3, and F-4. The first to fourth lateral parts F-1, F-2, F-3, and F-4 correspond to substantially one component, but will be described as being divided from one another for convenience of description. The first to fourth lateral parts F-1, F-2, F-3, and F-4 may be connected to define the frame opening F-OP. The first lateral part F-1 and the second lateral part F-2 may extend in the first direction DR1 and may be spaced apart from each other in the second direction DR2. The third lateral part F-3 and the fourth lateral part F-4 may extend in the second direction DR2 and may be spaced apart from each other in the first direction DR1. The third lateral part F-3 may be connected to one end of the first lateral part F-1 and one end of the second lateral part F-2, and the fourth lateral part F-4 may be connected to an opposite end of the first lateral part F-1 and an opposite end of the second lateral part F-2. Accordingly, the frame opening F-OP may be defined.

In this embodiment, the widths of the first lateral part F-1 and the second lateral part F-2 in the first direction DR1 may be greater than the widths of the third lateral part F-3 and the fourth lateral part F-4 in the second direction DR2. Accordingly, the first lateral part F-1 and the second lateral part F-2 may be defined as long sides of the frame FR, and the third lateral part F-3 and the fourth lateral part F-4 may be defined as short sides of the frame FR.

The open sheet OS may include a body part BD in which sheet openings S-OP overlapping the frame opening F-OP are defined and the connecting part CM protruding from the body part DB and at least partially overlapping the frame FR. The open sheet OS may have a thickness of about 50 micrometers (lam) to about 200 μm in the third direction DR3. The body part BD and the connecting part CM correspond to substantially one component, but will be described as being divided from each other for convenience of description.

The connecting part CM may include a first connecting part UC, a second connecting part BC, a third connecting part CL, and a fourth connecting part CR. The first connecting part UC may overlap the first lateral part F-1 and may extend in the first direction DR1. The first connecting part UC may overlap an entirety of the first lateral part F-1. When viewed in the second direction DR2, the first connecting part UC may overlap the sheet openings S-OP arranged in the first direction DR1.

The second connecting part BC may overlap the second lateral part F-2 and may extend in the first direction DR1. The second connecting part BC may overlap an entirety of the second lateral part F-2. When viewed in the second direction DR2, the second connecting part BC may overlap the sheet openings S-OP arranged in the first direction DR1. The second connecting part BC may be spaced apart from the first connecting part UC in the second direction DR2 with the body part BD therebetween.

The third connecting part CL may include a plurality of third connecting parts L-1, L-2, L-3, and L-4. The third connecting parts L-1, L-2, L-3, and L-4 may protrude in the first direction DR1 from the body part BD adjacent to the third lateral part F-3. One portion of each of the third connecting parts L-1, L-2, L-3, and L-4 may overlap the frame opening F-OP, and the remaining portion of each of the third connecting parts L-1, L-2, L-3, and L-4 may overlap the frame FR and may be coupled to the third lateral part F-3 of the frame FR. The third connecting parts L-1, L-2, L-3, and L-4 may be spaced apart from each other in the second direction DR2.

According to this embodiment, when viewed in the first direction DR1, the third connecting parts L-1, L-2, L-3, and L-4 may not overlap the sheet openings S-OP. Accordingly, the third connecting parts L-1, L-2, L-3, and L-4 may protrude from regions of the body part BD between the sheet openings S-OP.

As illustrated in FIG. 2, a first portion B1 of the body part BD adjacent to the third lateral part F-3 may be spaced apart from the third lateral part F-3 by a predetermined gap. In an embodiment, two third connecting parts CL adjacent to each other, the third lateral part F-3, and the first portion B1 may form an empty space SP that extends in the second direction DR2 in the plan view.

The fourth connecting part CR may include a plurality of fourth connecting parts R-1, R-2, R-3, and R-4. The fourth connecting parts R-1, R-2, R-3, and R-4 may protrude in the first direction DR1 from the body part BD adjacent to the fourth lateral part F-4. One portion of each of the fourth connecting parts R-1, R-2, R-3, and R-4 may overlap the frame opening F-OP, and the remaining portion of each of the fourth connecting parts R-1, R-2, R-3, and R-4 may overlap the frame FR and may be coupled to the fourth lateral part F-4 of the frame FR. The fourth connecting parts R-1, R-2, R-3, and R-4 may be spaced apart from each other in the second direction DR2.

According to this embodiment, when viewed in the first direction DR1, the fourth connecting parts R-1, R-2, R-3, and R-4 may not overlap the sheet openings S-OP. Accordingly, the fourth connecting parts R-1, R-2, R-3, and R-4 may protrude from regions of the body part BD between the sheet openings S-OP.

As illustrated in FIG. 2, a second portion B2 of the body part BD adjacent to the fourth lateral part F-4 may be spaced apart from the fourth lateral part F-4 by a predetermined gap. In an embodiment, two fourth connecting parts CR adjacent to each other, the fourth lateral part F-4, and the second portion B2 may form an empty space SP that extends in the second direction DR2 in the plan view.

Each of the masks MS according to the disclosure may include a deposition part M1 in which deposition openings M-OP are defined and the coupling parts M2-1 and M2-2 protruding from the deposition part M1 and overlapping the body part BD. Each of the masks MS may have a thickness of about 10 μm to about lam. Regions where the masks MS are disposed on the open sheet OS are illustrated by dotted lines.

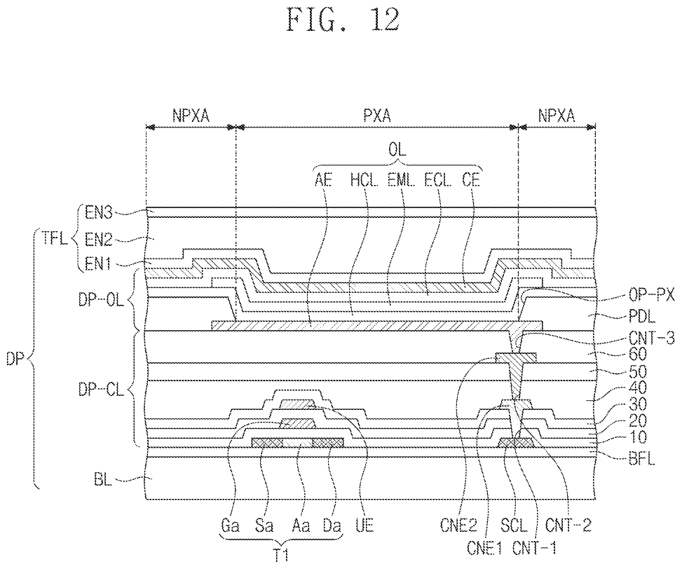

Deposition openings M-OP defined in one deposition part M1 may overlap one sheet opening S-OP corresponding thereto. The deposition material passing through the one sheet opening S-OP and the deposition openings M-OP corresponding thereto may form an emissive pattern EML (refer to FIG. 12) included in each of light-emitting elements OL (refer to FIG. 12) to be described below.

The coupling parts M2-1 and M2-2 may extend in the first direction DR1 and may be spaced apart from each other in the second direction DR2 with the deposition part M1 therebetween.

According to the disclosure, the coupling parts M2-1 and M2-2 included in each of the masks MS may extend in the same direction as the extension direction of a connecting part having a relatively large area coupled with the frame FR among the first to fourth connecting parts UC, BC, CL, and CR included in the open sheet OS.

In an embodiment, the areas by which the first and second connecting parts UC and BC are coupled with the frame FR may be greater than the areas by which the third and fourth connecting parts CL and CR are coupled with the frame FR, for example. The first and second connecting parts UC and BC may extend in the first direction DR1, and the coupling parts M2-1 and M2-2 may extend in the first direction DR1 accordingly. In this case, the arrangement direction of the welding protrusions WUO and WBO formed on the first and second connecting parts UC and BC and the arrangement direction of the welding protrusions WMO formed on the coupling parts M2-1 and M2-2 may be the same as each other in the first direction DR1.

According to this embodiment, the coupling parts M2-1 and M2-2 of each of the masks MS may extend in the extension direction of a connecting part of the open sheet OS that has a relatively large area coupled with the frame FR, and the mask MS may be coupled with the open sheet OS by performing a welding process on the coupling parts M2-1 and M2-2. Accordingly, the mask MS may be more stably coupled to the open sheet OS, and deformation of the open sheet OS depending on deformation of the mask MS may be minimized.

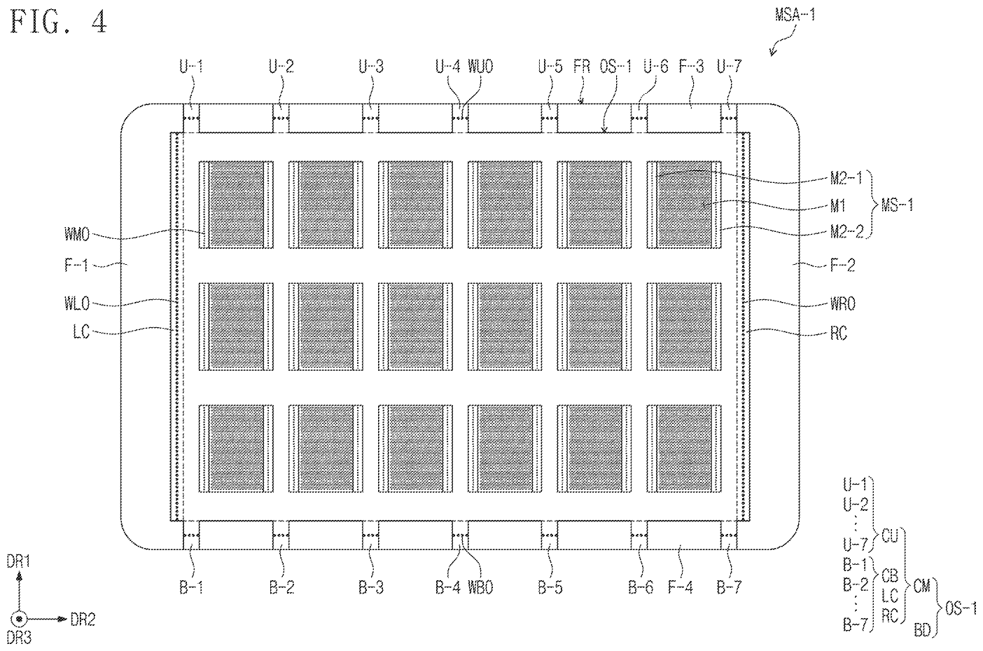

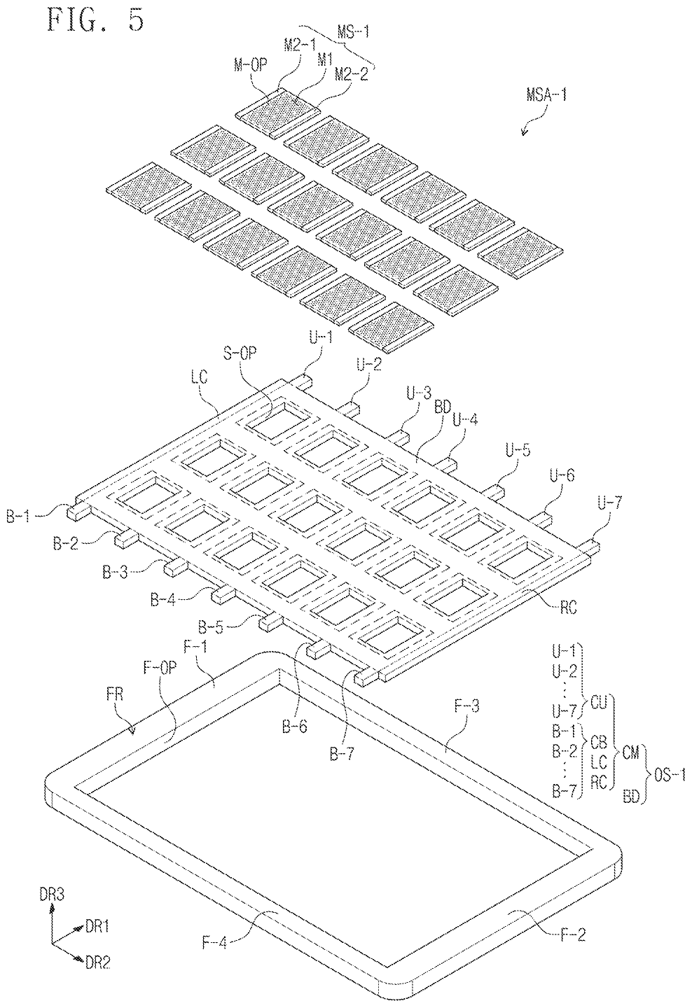

FIG. 4 is a plan view of an embodiment of a mask assembly according to the disclosure. FIG. 5 is an exploded perspective view of an embodiment of the mask assembly according to the disclosure. Components identical or similar to the components described with reference to FIGS. 1 to 3 will be assigned with identical or similar reference numerals, and repetitive descriptions will be omitted.

Referring to FIGS. 4 and 5, the mask assembly MSA-1 in an embodiment may include a frame FR, an open sheet OS-1, and masks MS-1.

The open sheet OS-1 may be disposed on the frame FR and may be coupled with the frame FR through a welding process. Welding protrusions WUO, WBO, WLO, and WRO formed in the welding process may be provided on portions of a connecting part CM of the open sheet OS-1 that are coupled with the frame FR. The masks MS-1 may be disposed on the open sheet OS-1 and may be coupled with the open sheet OS-1 through a welding process. Welding protrusions WMO formed in the welding process may be provided on coupling parts M2-1 and M2-2 of each of the masks MS-1.

The frame FR may include first to fourth lateral parts F-1, F-2, F-3, and F-4. The first to fourth lateral parts F-1, F-2, F-3, and F-4 correspond to substantially one component, but will be described as being divided from one another for convenience of description. The first to fourth lateral parts F-1, F-2, F-3, and F-4 may be connected to define a frame opening F-OP. The first lateral part F-1 and the second lateral part F-2 may extend in the first direction DR1 and may be spaced apart from each other in the second direction DR2. The third lateral part F-3 and the fourth lateral part F-4 may extend in the second direction DR2 and may be spaced apart from each other in the first direction DR1. The third lateral part F-3 may be connected to one end of the first lateral part F-1 and one end of the second lateral part F-2, and the fourth lateral part F-4 may be connected to an opposite end of the first lateral part F-1 and an opposite end of the second lateral part F-2. Accordingly, the frame opening F-OP may be defined.

In this embodiment, the widths of the first lateral part F-1 and the second lateral part F-2 in the first direction DR1 may be smaller than the widths of the third lateral part F-3 and the fourth lateral part F-4 in the second direction DR2. Accordingly, the first lateral part F-1 and the second lateral part F-2 may be defined as short sides of the frame FR, and the third lateral part F-3 and the fourth lateral part F-4 may be defined as long sides of the frame FR.

The open sheet OS-1 may include a body part BD in which sheet openings S-OP overlapping the frame opening F-OP are defined and the connecting part CM protruding from the body part DB and at least partially overlapping the frame FR. The open sheet OS-1 may have a thickness of about 50 μm to about 200 lam in the third direction DR3.

The connecting part CM may include a first connecting part LC, a second connecting part RC, a third connecting part CU, and a fourth connecting part CB. The first connecting part LC may overlap the first lateral part F-1 and may extend in the first direction DR1. The first connecting part LC may overlap an entirety of the first lateral part F-1. When viewed in the second direction DR2, the first connecting part LC may overlap the sheet openings S-OP arranged in the first direction DR1.

The second connecting part RC may overlap the second lateral part F-2 and may extend in the first direction DR1. The second connecting part RC may overlap an entirety of the second lateral part F-2. When viewed in the second direction DR2, the second connecting part RC may overlap the sheet openings S-OP arranged in the first direction DR1. The second connecting part RC may be spaced apart from the first connecting part LC in the second direction DR2 with the body part BD therebetween.

The third connecting part CU may include a plurality of third connecting parts U-1, U-2, U-3, U-4, U-5, U-6, and U-7. The third connecting parts U-1, U-2, U-3, U-4, U-5, U-6, and U-7 may protrude in the first direction DR1 from the body part BD adjacent to the third lateral part F-3. The third connecting parts U-1, U-2, U-3, U-4, U-5, U-6, and U-7 may overlap the frame FR and may be coupled to the third lateral part F-3 of the frame FR. The third connecting parts U-1, U-2, U-3, U-4, U-5, U-6, and U-7 may be spaced apart from each other in the second direction DR2.

According to this embodiment, when viewed in the first direction DR1, the third connecting parts U-1, U-2, U-3, U-4, U-5, U-6, and U-7 may not overlap the sheet openings S-OP. Accordingly, the third connecting parts U-1, U-2, U-3, U-4, U-5, U-6, and U-7 may protrude from regions of the body part BD between the sheet openings S-OP.

The fourth connecting part CB may include a plurality of fourth connecting parts B-1, B-2, B-3, B-4, B-5, B-6, and B-7. The fourth connecting parts B-1, B-2, B-3, B-4, B-5, B-6, and B-7 may protrude in the first direction DR1 from the body part BD adjacent to the fourth lateral part F-4. The fourth connecting parts B-1, B-2, B-3, B-4, B-5, B-6, and B-7 may overlap the frame FR and may be coupled to the fourth lateral part F-4 of the frame FR. The fourth connecting parts B-1, B-2, B-3, B-4, B-5, B-6, and B-7 may be spaced apart from each other in the second direction DR2.

According to this embodiment, when viewed in the first direction DR1, the fourth connecting parts B-1, B-2, B-3, B-4, B-5, B-6, and B-7 may not overlap the sheet openings S-OP. Accordingly, the fourth connecting parts B-1, B-2, B-3, B-4, B-5, B-6, and B-7 may protrude from regions of the body part BD between the sheet openings S-OP.

Each of the masks MS-1 according to the disclosure may include a deposition part M1 in which deposition openings M-OP are defined and the coupling parts M2-1 and M2-2 protruding from the deposition part M1 and overlapping the body part BD. Each of the masks MS-1 may have a thickness of about 10 μm to about 30 μm in the third direction DR3.

Deposition openings M-OP defined in one deposition part M1 may overlap one sheet opening S-OP corresponding thereto. A deposition material passing through the one sheet opening S-OP and the deposition openings M-OP corresponding thereto may form an emissive pattern EML (refer to FIG. 12) included in each of light-emitting elements OL (refer to FIG. 12) to be described below.

The coupling parts M2-1 and M2-2 may extend in the first direction DR1 and may be spaced apart from each other in the second direction DR2 with the deposition part M1 therebetween.

According to the disclosure, the coupling parts M2-1 and M2-2 included in each of the masks MS-1 may extend in the same direction as the extension direction of a connecting part having a relatively large area coupled with the frame FR among the first to fourth connecting parts LC, RC, CU, and CB included in the open sheet OS-1.

In an embodiment, the areas by which the first and second connecting parts LC and RC are coupled with the frame FR may be greater than the areas by which the third and fourth connecting parts CU and CB are coupled with the frame FR, for example. The first and second connecting parts LC and RC may extend in the first direction DR1, and the coupling parts M2-1 and M2-2 may extend in the first direction DR1 accordingly. In this case, the arrangement direction of the welding protrusions WLO and WRO formed on the first and second connecting parts LC and RC and the arrangement direction of the welding protrusions WMO formed on the coupling parts M2-1 and M2-2 may be the same as each other in the first direction DR1.

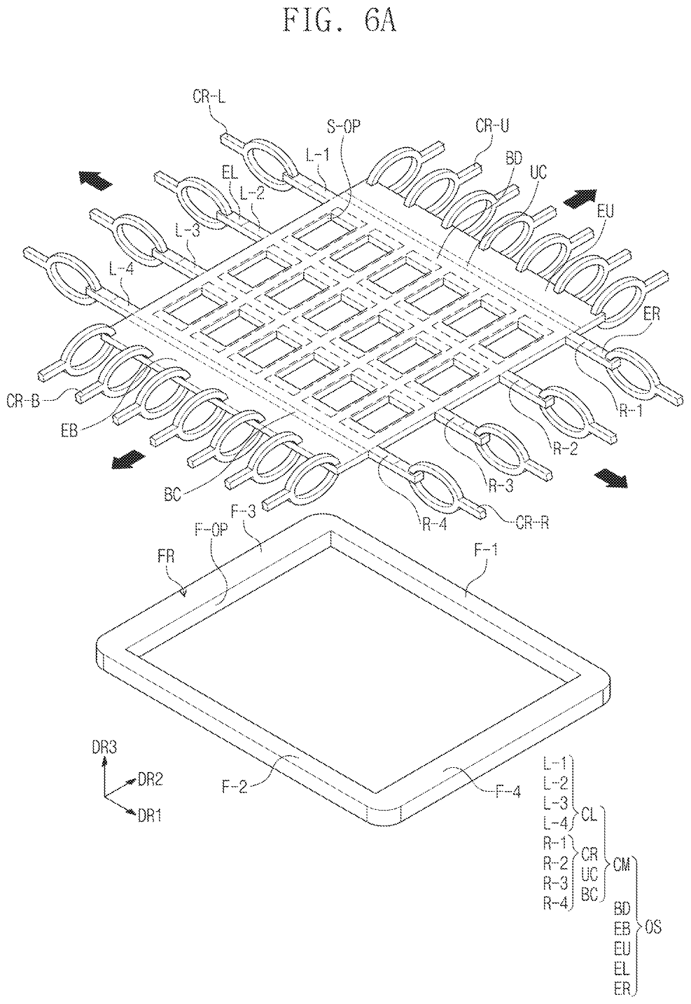

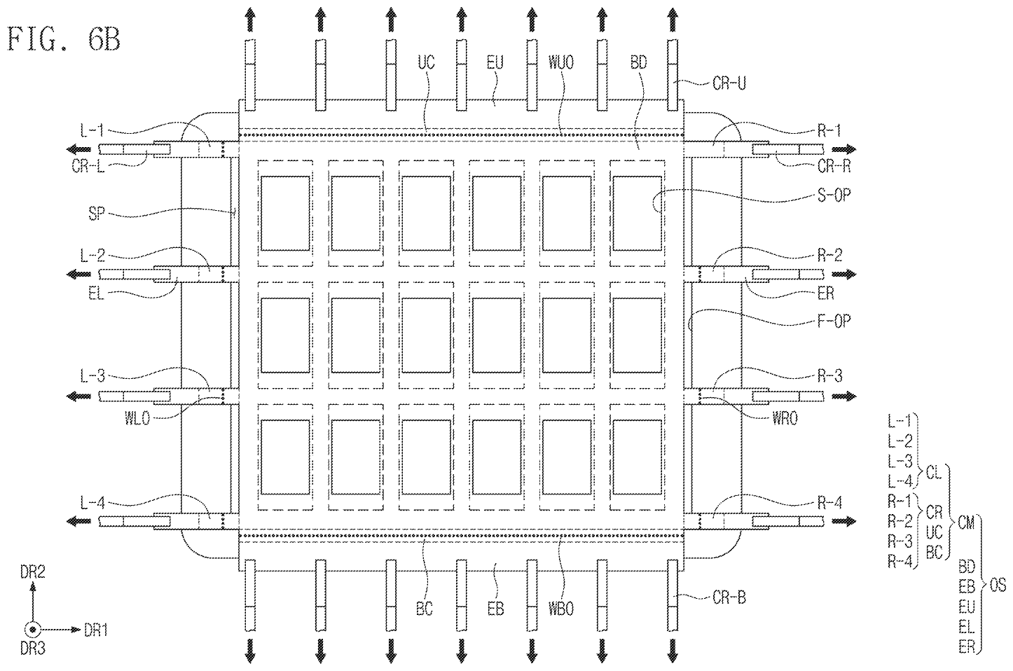

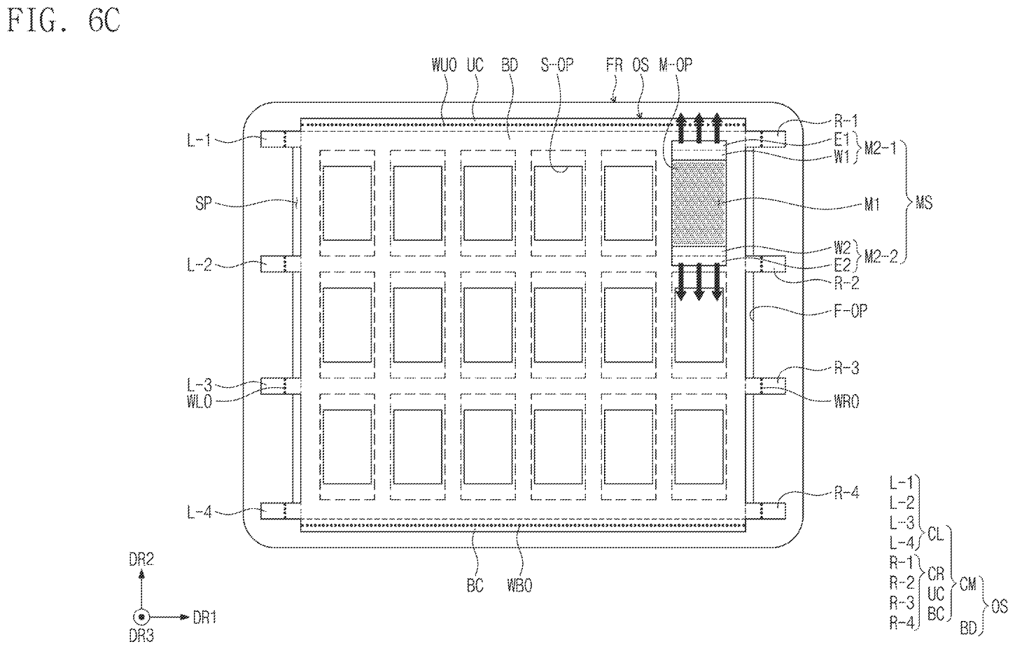

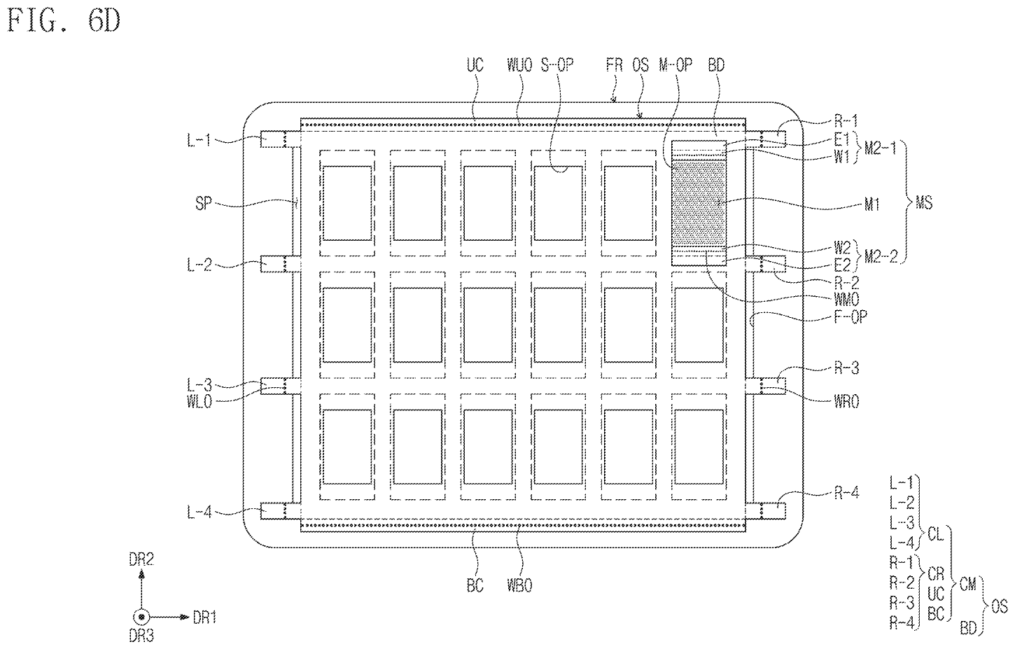

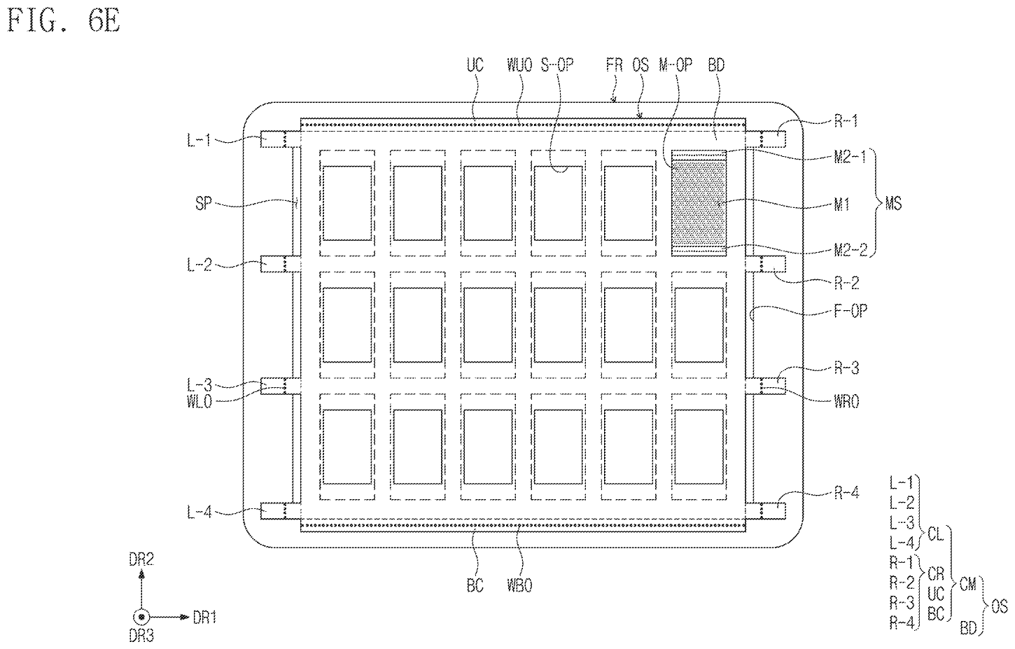

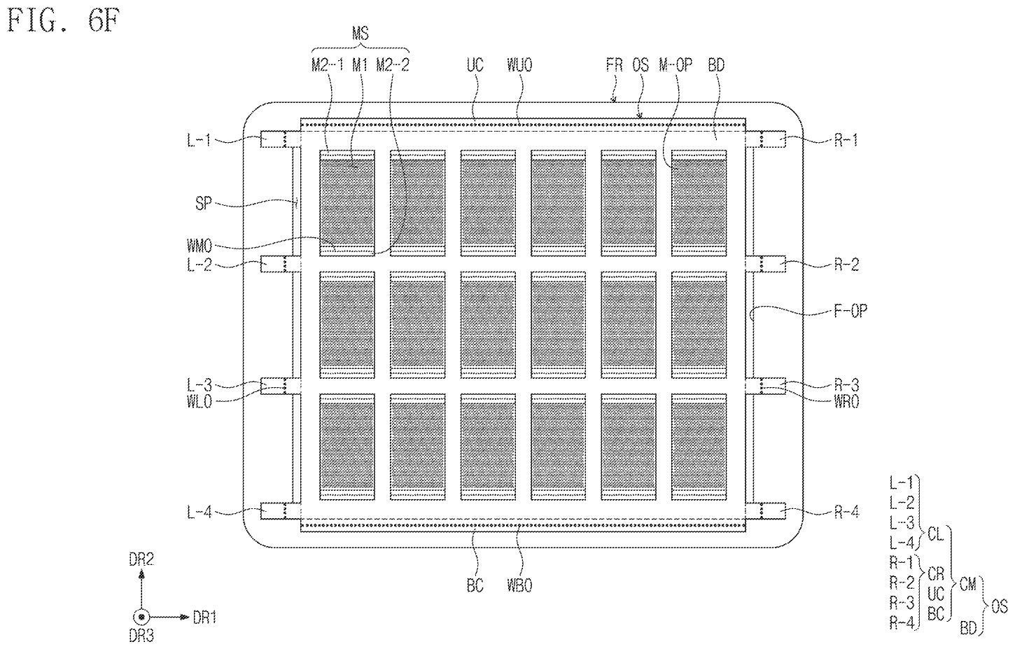

FIG. 6A is a perspective view illustrating an embodiment of a mask assembly manufacturing method according to the disclosure. FIG. 6B is a plan view illustrating an embodiment of the mask assembly manufacturing method according to the disclosure. FIG. 6C is a plan view illustrating an embodiment of the mask assembly manufacturing method according to the disclosure. FIG. 6D is a plan view illustrating an embodiment of the mask assembly manufacturing method according to the disclosure. FIG. 6E is a plan view illustrating an embodiment of the mask assembly manufacturing method according to the disclosure.

Referring to FIG. 6A, the mask assembly manufacturing method in an embodiment may include an operation of providing a frame FR.

The frame FR may include first to fourth lateral parts F-1, F-2, F-3, and F-4. The first to fourth lateral parts F-1, F-2, F-3, and F-4 may be connected to define a frame opening F-OP. The first lateral part F-1 and the second lateral part F-2 may extend in the first direction DR1 and may be spaced apart from each other in the second direction DR2. The third lateral part F-3 and the fourth lateral part F-4 may extend in the second direction DR2 and may be spaced apart from each other in the first direction DR1. The third lateral part F-3 may be connected to one end of the first lateral part F-1 and one end of the second lateral part F-2, and the fourth lateral part F-4 may be connected to an opposite end of the first lateral part F-1 and an opposite end of the second lateral part F-2. Accordingly, the frame opening F-OP may be defined.

The mask assembly manufacturing method in an embodiment may include an operation of stretching an open sheet OS. The open sheet OS may include a body part BD in which sheet openings S-OP overlapping the frame opening F-OP are defined and a connecting part CM protruding from the body part DB and at least partially overlapping the frame FR. The open sheet OS in an embodiment may further include dummy parts EU, EB, EL, and ER protruding from the connecting part CM.

In the operation of stretching the open sheet OS, clamps CR-U, CR-B, CR-L, and CR-R may be connected to the dummy parts EU, EB, EL, and ER, respectively, and the open sheet OS may be stretched in the directions in which the dummy parts EU, EB, EL, and ER protrude from the connecting part CM.

The connecting part CM may include a first connecting part UC, a second connecting part BC, a third connecting part CL, and a fourth connecting part CR. The first connecting part UC may overlap the first lateral part F-1 and may extend in the first direction DR1. The first connecting part UC may overlap an entirety of the first lateral part F-1. When viewed in the second direction DR2, the first connecting part UC may overlap the sheet openings S-OP arranged in the first direction DR1.

The first dummy part EU may protrude from the first connecting part UC in the second direction DR2 and may extend in the first direction DR1. The first clamps CR-U may be connected to the first dummy part EU and may be spaced apart from each other in the first direction DR1. The first clamps CR-U may stretch the first dummy part EU in the second direction DR2. According to this embodiment, the first clamps CR-U connected to the first dummy part EU may not overlap the sheet openings S-OP when viewed in the second direction DR2.

The second connecting part BC may overlap the second lateral part F-2 and may extend in the first direction DR1. The second connecting part BC may overlap an entirety of the second lateral part F-2. When viewed in the second direction DR2, the second connecting part BC may overlap the sheet openings S-OP arranged in the first direction DR1. The second connecting part BC may be spaced apart from the first connecting part UC in the second direction DR2 with the body part BD therebetween.

The second dummy part EB may protrude from the second connecting part BC in the second direction DR2 and may extend in the first direction DR1. The second clamps CR-B may be connected to the second dummy part EB and may be spaced apart from each other in the first direction DR1. The second clamps CR-B may stretch the second dummy part EB in the second direction DR2. According to this embodiment, the second clamps CR-B connected to the second dummy part EB may not overlap the sheet openings S-OP when viewed in the second direction DR2.

The third connecting part CL may include a plurality of third connecting parts L-1, L-2, L-3, and L-4. The third connecting parts L-1, L-2, L-3, and L-4 may protrude in the first direction DR1 from the body part BD adjacent to the third lateral part F-3. The third connecting parts L-1, L-2, L-3, and L-4 may be spaced apart from each other in the second direction DR2.

As many third dummy parts EL as the third connecting parts L-1, L-2, L-3, and L-4 may be provided. Each of the third dummy parts EL may protrude in the first direction DR1 from a corresponding connecting part among the third connecting parts L-1, L-2, L-3, and L-4. The third clamps CR-L may be connected to the corresponding third dummy parts EL and may be spaced apart from each other in the second direction DR2. The third clamps CR-L may stretch the corresponding third dummy parts EL in the first direction DR1.

The fourth connecting part CR may include a plurality of fourth connecting parts R-1, R-2, R-3, and R-4. The fourth connecting parts R-1, R-2, R-3, and R-4 may protrude in the first direction DR1 from the body part BD adjacent to the fourth lateral part F-4. The fourth connecting parts R-1, R-2, R-3, and R-4 may be spaced apart from each other in the second direction DR2.

As many fourth dummy parts ER as the fourth connecting parts R-1, R-2, R-3, and R-4 may be provided. Each of the fourth dummy parts ER may protrude in the first direction DR1 from a corresponding connecting part among the fourth connecting parts R-1, R-2, R-3, and R-4. The fourth clamps CR-R may be connected to the corresponding fourth dummy parts ER and may be spaced apart from each other in the second direction DR2. The fourth clamps CR-R may stretch the corresponding fourth dummy parts ER in the first direction DR1.

The first to fourth clamps CR-U, CR-B, CR-L, and CR-R may simultaneously stretch the open sheet OS in corresponding directions. The open sheet OS may be disposed on the frame FR in the state of being stretched. However, without being limited thereto, the open sheet OS may be stretched through the first to fourth clamps CR-U, CR-B, CR-L, and CR-R in a state in which the open sheet OS is disposed on the frame FR and is not limited to any particular embodiment.

According to this embodiment, the first clamps CR-U and the second clamps CR-B connected adjacent to the first connecting part UC and the second connecting part BC that overlap an entirety of the frame FR may be connected to portions of the body part BD between adjacent sheet openings S-OP and may stretch the open sheet OS, and thus deformation of the sheet openings S-OP may be minimized in the operation of stretching the open sheet OS. Accordingly, a mask assembly MSA (refer to FIG. 3) with improved precision may be provided.

Referring to FIG. 6B, the mask assembly manufacturing method in an embodiment may include an operation of coupling the first to fourth connecting parts UC, BC, CL, and CR to the frame FR through a welding process. The operation of coupling the first to fourth connecting parts UC, BC, CL, and CR to the frame FR may be performed in the state in which the open sheet OS is stretched by the first to fourth clamps CR-U, CR-B, CR-L, and CR-R.

The first connecting part UC may be coupled to the first lateral part F-1 (refer to FIG. 6A) of the frame FR. First welding protrusions WUO may be formed on the first connecting part UC by the welding process. The first welding protrusions WUO may be arranged in the first direction DR1 to correspond to the width by which the first connecting part UC extends. Accordingly, the first connecting part UC may be entirely coupled to the frame FR.

The second connecting part BC may be coupled to the second lateral part F-2 (refer to FIG. 6A) of the frame FR. Second welding protrusions WBO may be formed on the second connecting part BC by the welding process. The second welding protrusions WBO may be arranged in the first direction DR1 to correspond to the width by which the second connecting part BC extends. Accordingly, the second connecting part BC may be entirely coupled to the frame FR.

The third connecting part CL may include the plurality of third connecting parts L-1, L-2, L-3, and L-4. The plurality of third connecting parts L-1, L-2, L-3, and L-4 may be coupled to the third lateral part F-3 (refer to FIG. 6A) of the frame FR and may be spaced apart from each other in the second direction DR2. Third welding protrusions WLO may be formed on the respective third connecting parts L-1, L-2, L-3, and L-4 by the welding process. The third welding protrusions WLO may be arranged in the second direction DR2 to correspond to the widths by which the third connecting parts L-1, L-2, L-3, and L-4 extend.

The fourth connecting part CR may include the plurality of fourth connecting parts R-1, R-2, R-3, and R-4. The plurality of fourth connecting parts R-1, R-2, R-3, and R-4 may be coupled to the fourth lateral part F-4 (refer to FIG. 6A) of the frame FR and may be spaced apart from each other in the second direction DR2. Fourth welding protrusions WRO may be formed on the respective fourth connecting parts R-1, R-2, R-3, and R-4 by the welding process. The fourth welding protrusions WRO may be arranged in the second direction DR2 to correspond to the widths by which the fourth connecting parts R-1, R-2, R-3, and R-4 extend.

In an embodiment, the third lateral part F-3 (refer to FIG. 6A) of the frame FR and a portion of the body part BD adjacent to the third connecting part CL may be spaced apart from each other with a predetermined space SP therebetween in the plan view. Furthermore, the fourth lateral part F-4 (refer to FIG. 6A) of the frame FR and a portion of the body part BD adjacent to the fourth connecting part CR may be spaced apart from each other with a predetermined space SP therebetween in the plan view.

Referring to FIG. 6C, the mask assembly manufacturing method in an embodiment may further include an operation of removing the dummy parts EU, EB, EL, and ER from the open sheet OS. The dummy parts EU, EB, EL, and ER may be removed from the open sheet OS by an etching process.

The mask assembly manufacturing method in an embodiment may include an operation of stretching a mask MS. An operation of placing the mask MS on the open sheet OS and the operation of stretching the mask MS may be simultaneously performed and are not limited to any particular embodiment.

The mask MS may include a deposition part M1 in which deposition openings M-OP overlapping one sheet opening S-OP are defined and coupling parts M2-1 and M2-2 protruding from the deposition part M1 and overlapping the body part BD.

The coupling parts M2-1 and M2-2 may be spaced apart from each other in the second direction DR2 with the deposition part M1 therebetween. The first coupling part M2-1 may include a 1-1-th portion W1 protruding from one side of the deposition part M1 and a 2-1-th portion E1 protruding from the 1-1-th portion W1. The second coupling part M2-2 may include a 1-2-th portion W2 protruding from an opposite side of the deposition part M1 and a 2-2-th portion E2 protruding from the 1-2-th portion W2.

In the operation of stretching the mask MS, the 2-1-th portion E1 may be stretched through a separate structure (e.g., a clamp) in the direction in which the 2-1-th portion E1 protrudes, and the 2-2-th portion E2 may be stretched through the separate structure (e.g., a clamp) in the direction in which the 2-2-th portion E2 protrudes.

Referring to FIG. 6D, the mask assembly manufacturing method in an embodiment may include an operation of coupling the coupling parts M2-1 and M2-2 to the open sheet OS through a welding process. A region where one mask MS is disposed on the open sheet OS is illustrated by a dotted line.

The operation of coupling the coupling parts M2-1 and M2-2 to the open sheet OS may be performed by welding the 1-1-th portion W1 to the overlapping body part BD and welding the 1-2-th portion W2 to the overlapping body part BD. Accordingly, welding protrusions WMO may be formed on the 1-1-th portion W1 and the 1-2-th portion W2. The welding protrusions WMO may be arranged in the first direction DR1 to correspond to the widths by which the 1-1-th portion W1 and the 1-2-th portion W2 extend. Accordingly, the 1-1-th portion W1 and the 1-2-th portion W2 may be entirely coupled to the open sheet OS.

Referring to FIG. 6E, the mask assembly manufacturing method in an embodiment may further include an operation of removing the second portions E1 and E2 from the mask MS. The second portions E1 and E2 may be removed by an etching process.

According to the disclosure, the mask MS may be coupled to the open sheet OS in a state in which only the second portions E1 and E2 protruding from two sides spaced apart from each other in the second direction DR2 among four sides of the deposition part M1 are stretched and two sides spaced apart from each other in the first direction DR1 are not stretched.

Accordingly, a tensile force applied to the mask MS may be reduced, compared to that applied to a comparative mask, four sides of which are stretched with respect to the body part BD. In a case in which the comparative mask is coupled to the open sheet OS in the state in which the four sides of the comparative mask are stretched, a restoring force to return the comparative mask to the initial state before the comparative mask is stretched acts on the comparative mask, which causes not only deformation of the comparative mask, the four sides of which are stretched, but also deformation of the open sheet OS coupled with the comparative mask. The deformation of the comparative mask and/or the deformation of the open sheet OS may cause a deposition defect.

According to the disclosure, the mask MS may be coupled to the open sheet OS in the state in which the two sides of the mask MS are stretched. Thus, a tensile force applied to the mask MS may be reduced, and a restoring force of the mask MS may also be reduced in the state in which the mask MS is coupled to the open sheet OS. Accordingly, tensile deformation of the mask MS may be minimized, and deformation of the open sheet OS may be decreased at the same time.

The mask assembly MSA according to the disclosure includes the mask MS and the open sheet OS capable of minimizing tensile deformation and deformation by heat generated in a deposition process. Accordingly, the mask assembly MSA with improved deposition precision and the manufacturing method thereof may be provided.

Referring to FIG. 6F, in the mask assembly manufacturing method in an embodiment, a plurality of masks MS may be coupled to the open sheet OS by repeatedly performing the operation of stretching/placing the mask MS, the operation of coupling the coupling parts M2-1 and M2-2 to the open sheet OS, and the operation of removing the second portions E1 and E2 of the mask MS from the mask MS, which have been described above with reference to FIGS. 6C to 6E. According to the disclosure, since the masks MS are separately coupled to the open sheet OS, a defective mask among the masks MS may be separately replaced.

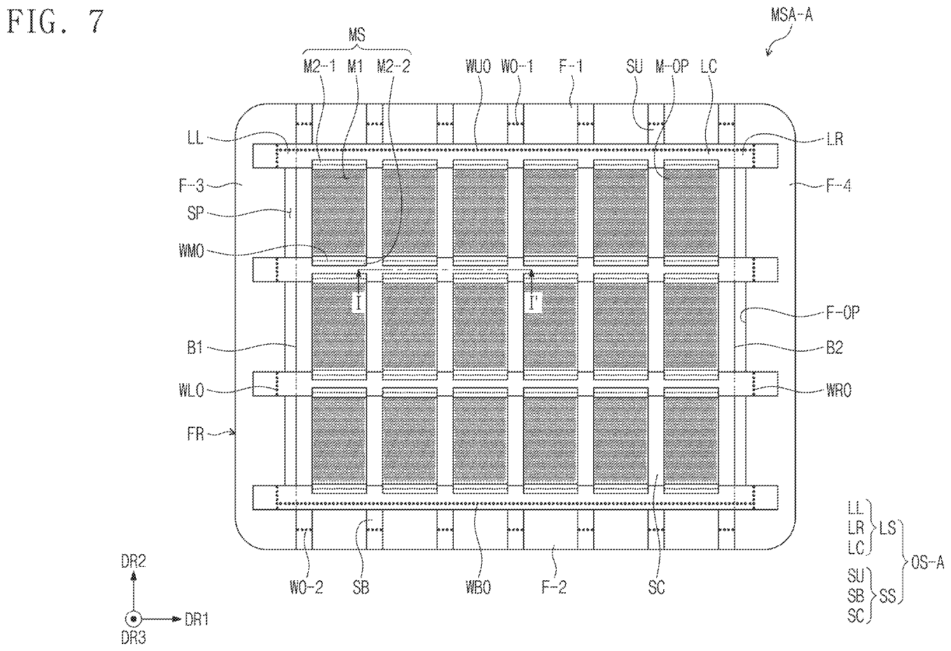

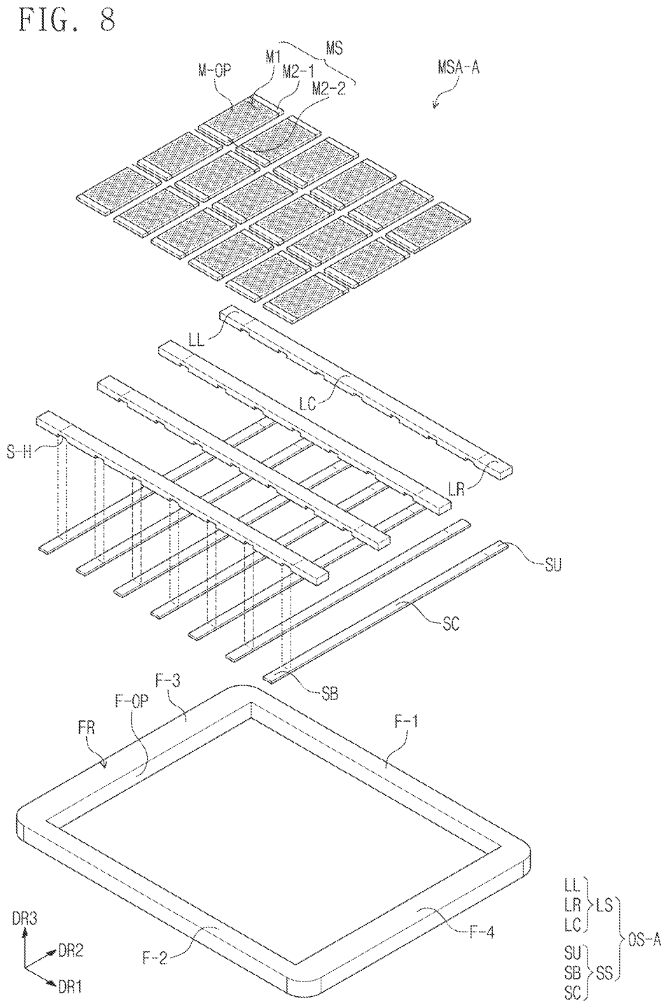

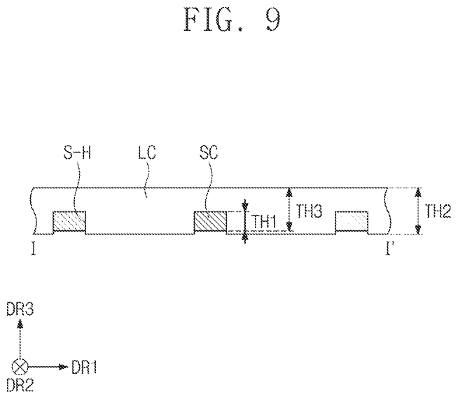

FIG. 7 is a plan view of an embodiment of a mask assembly according to the disclosure. FIG. 8 is an exploded perspective view of an embodiment of the mask assembly according to the disclosure. FIG. 9 is a cross-sectional view taken along line I-I′ of FIG. 7.

Referring to FIGS. 7 and 8, the mask assembly MSA-A may include a frame FR, an open sheet OS-A, and a plurality of masks MS. The frame FR, the open sheet OS-A, and the masks MS may include one of invar and stainless steel.

The frame FR may include first to fourth lateral parts F-1, F-2, F-3, and F-4. The first to fourth lateral parts F-1, F-2, F-3, and F-4 may be connected to define a frame opening F-OP. The first lateral part F-1 and the second lateral part F-2 may extend in the first direction DR1 and may be spaced apart from each other in the second direction DR2. The third lateral part F-3 and the fourth lateral part F-4 may extend in the second direction DR2 and may be spaced apart from each other in the first direction DR1. The third lateral part F-3 may be connected to one end of the first lateral part F-1 and one end of the second lateral part F-2, and the fourth lateral part F-4 may be connected to an opposite end of the first lateral part F-1 and an opposite end of the second lateral part F-2. Accordingly, the frame opening F-OP may be defined.

The open sheet OS-A in an embodiment may include a plurality of first sticks LS and a plurality of second sticks SS. The first sticks LS may extend in the first direction DR1 and may be spaced apart from each other in the second direction DR2. The second sticks SS may extend in the second direction DR2 and may be spaced apart from each other in the first direction DR1. In this embodiment, the widths of the first sticks LS in the first direction DR1 may be greater than the widths of the second sticks SS in the second direction DR2.

Each of the first sticks LS may include a 1-1-th connecting portion LL, a 1-2-th connecting portion LR, and a first central portion LC. The 1-1-th connecting portion LL may be spaced apart from the 1-2-th connecting portion LR in the first direction DR1 with the first central portion LC therebetween.

The 1-1-th connecting portions LL may overlap the third lateral part F-3 of the frame FR and may be coupled with the third lateral part F-3 through a welding process. Welding protrusions WLO may be formed on the 1-1-th connecting portions LL through the welding process.

The 1-2-th connecting portions LR may overlap the fourth lateral part F-4 of the frame FR and may be coupled with the fourth lateral part F-4 through a welding process. Welding protrusions WRO may be formed on the 1-2-th connecting portions LR through the welding process.

According to this embodiment, the first central portion LC of the first stick LS overlapping the first lateral part F-1 among the first sticks LS may be coupled with the first lateral part F-1 through a welding process. Accordingly, upper welding protrusions WUO arranged in the first direction DR1 may be formed on the first central portion LC of the first stick LS. The first central portion LC of the first stick LS overlapping the second lateral part F-2 among the first sticks LS may be coupled with the second lateral part F-2 through a welding process. Accordingly, lower welding protrusions WBO arranged in the first direction DR1 may be formed on the first central portion LC of the first stick LS overlapping the second lateral part F-2.

Each of the second sticks SS may include a 2-1-th connecting portion SU, a 2-2-th connecting portion SB, and a second central portion SC. The 2-1-th connecting portion SU may be spaced apart from the 2-2-th connecting portion SB in the second direction DR2 with the second central portion SC therebetween.

The 2-1-th connecting portions SU may overlap the first lateral part F-1 of the frame FR and may be coupled with the first lateral part F-1 through a welding process. Welding protrusions WO-1 may be formed on the 2-1-th connecting portions SU through the welding process.

The 2-2-th connecting portions SB may overlap the second lateral part F-2 of the frame FR and may be coupled with the second lateral part F-2 through a welding process. Welding protrusions WO-2 may be formed on the 2-2-th connecting portions SB through the welding process.

According to this embodiment, the second stick SS closest to the third lateral part F-3 among the second sticks SS may be spaced apart from the third lateral part F-3 with an empty space SP therebetween. Furthermore, the second stick SS closest to the fourth lateral part F-4 among the second sticks SS may be spaced apart from the fourth lateral part F-4 with an empty space SP therebetween.

According to this embodiment, the second sticks SS intersecting the first sticks LS in the region overlapping the frame opening F-OP may be inserted into stick recesses S-H defined on the first central portions LC of the first sticks LS. More specifically, the second central portions SC may be inserted into the stick recesses 5-H defined on the first central portions LC. Accordingly, in this embodiment, the first sticks LS may be disposed on the second sticks SS.

Referring to FIG. 9, the first thickness TH1 of the second central portion SC in the third direction DR3 may be smaller than the second thickness TH2 of the first central portion LC in the third direction DR3. Furthermore, in the state in which the second central portion SC is inserted into the corresponding stick recess S-H, the third thickness TH3 of the first central portion LC and the second central portion SC may be about 90% to about 100% of the second thickness TH2. Thus, according to this embodiment, a step due to the intersection of the first sticks LS and the second sticks SS may be cancelled.

Each of the masks MS may include a deposition part M1 in which deposition openings M-OP are defined and coupling parts M2-1 and M2-2 protruding from the deposition part M1 and overlapping a body part BD.

The first coupling part M2-1 may be spaced apart from the second coupling part M2-2 in the second direction DR2 with the deposition part M1 therebetween. The first coupling part M2-1 and the second coupling part M2-2 may be coupled, through a welding process, to the first central portions LC overlapping the first coupling part M2-1 and the second coupling part M2-2. Accordingly, welding protrusions WMO formed through the welding process and arranged in the first direction DR1 may be formed on the first coupling part M2-1 and the second coupling part M2-2.

According to this embodiment, the outer first sticks LS overlapping the first lateral part F-1 and the second lateral part F-2 among the first sticks LS may be more stably coupled to the frame FR than the second sticks SS since the entirety of the regions of the outer first sticks LS that overlap the first lateral part F-1 and the second lateral part F-2 are coupled to the frame FR. Accordingly, even though the masks MS are coupled to the corresponding first central portions LC in a state of being stretched in the second direction DR2, a restoring force against the tension of the masks MS may be cancelled, and thus the mask assembly MSA-A in which deformation of the frame FR is reduced may be provided.

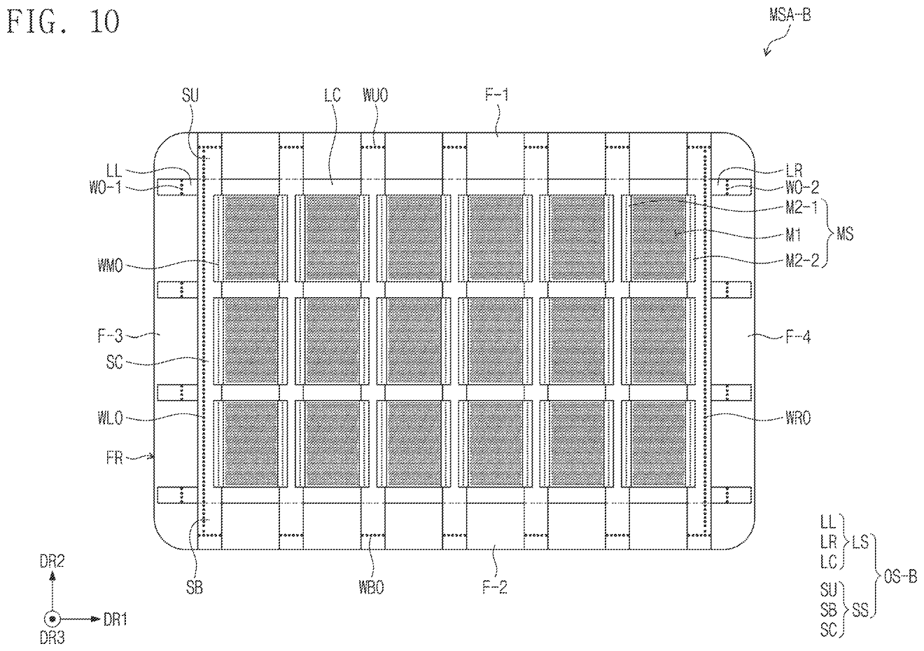

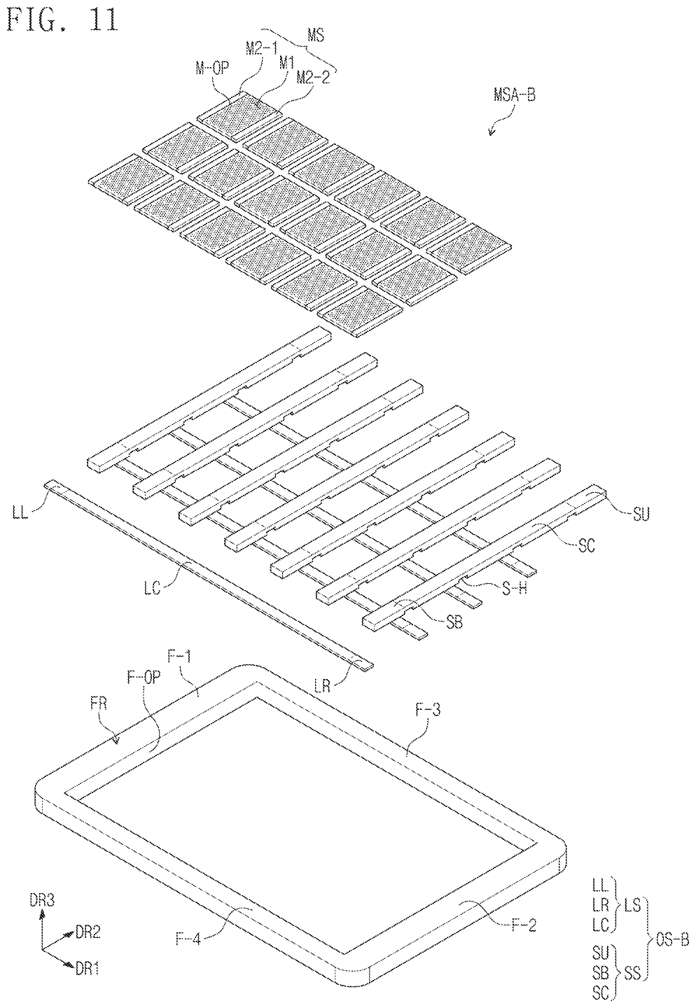

FIG. 10 is a plan view of an embodiment of a mask assembly according to the disclosure. FIG. 11 is an exploded perspective view of an embodiment of the mask assembly according to the disclosure. Referring to FIGS. 10 and 11, the mask assembly MSA-B may include a frame FR, an open sheet OS-B, and a plurality of masks MS. The frame FR, the open sheet OS-B, and the masks MS may include one of invar and stainless steel.

The frame FR may include first to fourth lateral parts F-1, F-2, F-3, and F-4. The first to fourth lateral parts F-1, F-2, F-3, and F-4 may be connected to define a frame opening F-OP. The first lateral part F-1 and the second lateral part F-2 may extend in the first direction DR1 and may be spaced apart from each other in the second direction DR2. The third lateral part F-3 and the fourth lateral part F-4 may extend in the second direction DR2 and may be spaced apart from each other in the first direction DR1. The third lateral part F-3 may be connected to one end of the first lateral part F-1 and one end of the second lateral part F-2, and the fourth lateral part F-4 may be connected to an opposite end of the first lateral part F-1 and an opposite end of the second lateral part F-2. Accordingly, the frame opening F-OP may be defined.

The open sheet OS-B according to this embodiment may include a plurality of first sticks LS and a plurality of second sticks SS. The first sticks LS may extend in the first direction DR1 and may be spaced apart from each other in the second direction DR2. The second sticks SS may extend in the second direction DR2 and may be spaced apart from each other in the first direction DR1. In this embodiment, the widths of the first sticks LS in the first direction DR1 may be greater than the widths of the second sticks SS in the second direction DR2.

Each of the first sticks LS may include a 1-1-th connecting portion LL, a 1-2-th connecting portion LR, and a first central portion LC. The 1-1-th connecting portion LL may be spaced apart from the 1-2-th connecting portion LR in the first direction DR1 with the first central portion LC therebetween.

The 1-1-th connecting portions LL may overlap the third lateral part F-3 of the frame FR and may be coupled with the third lateral part F-3 through a welding process. Welding protrusions WO-1 may be formed on the 1-1-th connecting portions LL through the welding process.

The 1-2-th connecting portions LR may overlap the fourth lateral part F-4 of the frame FR and may be coupled with the fourth lateral part F-4 through a welding process. Welding protrusions WO-2 may be formed on the 1-2-th connecting portions LR through the welding process.

Each of the second sticks SS may include a 2-1-th connecting portion SU, a 2-2-th connecting portion SB, and a second central portion SC. The 2-1-th connecting portion SU may be spaced apart from the 2-2-th connecting portion SB in the second direction DR2 with the second central portion SC therebetween.

The 2-1-th connecting portions SU may overlap the first lateral part F-1 of the frame FR and may be coupled with the first lateral part F-1 through a welding process. Welding protrusions WUO may be formed on the 2-1-th connecting portions SU through the welding process.

The 2-2-th connecting portions SB may overlap the second lateral part F-2 of the frame FR and may be coupled with the second lateral part F-2 through a welding process. Welding protrusions WBO may be formed on the 2-2-th connecting portions SB through the welding process.

According to this embodiment, the second central portion SC of the second stick SS overlapping the third lateral part F-3 among the second sticks SS may be coupled with the third lateral part F-3 through a welding process. Accordingly, left welding protrusions WLO arranged in the second direction DR2 may be formed on the second central portion SC of the second stick SS. The second central portion SC of the second stick SS overlapping the fourth lateral part F-4 among the second sticks SS may be coupled with the fourth lateral part F-4 through a welding process. Accordingly, right welding protrusions WRO arranged in the second direction DR2 may be formed on the second central portion SC of the second stick SS that overlaps the fourth lateral part F-4.

According to this embodiment, the first sticks LS intersecting the second sticks SS in the region overlapping the frame opening F-OP may be inserted into stick recesses S-H defined on the second central portions SC of the second sticks SS. More specifically, the first central portions LC may be inserted into the stick recesses S-H defined on the second central portions SC. Accordingly, in this embodiment, the first sticks LS may be disposed under the second sticks SS. The thickness in the state in which the first sticks LS are inserted into the corresponding stick recesses S-H may be about 90% to about 100% of the thickness of the second sticks SS. Thus, according to this embodiment, a step due to the intersection of the first sticks LS and the second sticks SS may be cancelled.

Each of the masks MS may include a deposition part M1 in which deposition openings M-OP are defined and coupling parts M2-1 and M2-2 protruding from the deposition part M1 and overlapping a body part BD.

The first coupling part M2-1 may be spaced apart from the second coupling part M2-2 in the second direction DR2 with the deposition part M1 therebetween. The first coupling part M2-1 and the second coupling part M2-2 may be coupled, through a welding process, to the second central portions SC overlapping the first coupling part M2-1 and the second coupling part M2-2. Accordingly, welding protrusions WMO formed through the welding process and arranged in the second direction DR2 may be formed on the first coupling part M2-1 and the second coupling part M2-2.

According to this embodiment, the outer second sticks SS overlapping the third lateral part F-3 and the fourth lateral part F-4 among the second sticks SS may be more stably coupled to the frame FR than the first sticks LS since the entirety of the regions of the outer second sticks SS that overlap the third lateral part F-3 and the fourth lateral part F-4 are coupled to the frame FR. Accordingly, even though the masks MS are coupled to the corresponding second central portions SC in a state of being stretched in the first direction DR1, a restoring force against the tension of the masks MS may be cancelled, and thus the mask assembly MSA-B in which deformation of the frame FR is reduced may be provided.

FIG. 12 is a cross-sectional view of an embodiment of a display panel according to the disclosure.

At least one of components of the display panel DP, which will be described below with reference to FIG. 12, may be formed through the deposition apparatus EA described above with reference to FIG. 1.

Referring to FIG. 12, the display panel DP may be an emissive display panel. In an embodiment, the display panel DP may be an organic light-emitting display panel, an inorganic light-emitting display panel, or a quantum-dot light-emitting display panel. An emissive layer of the organic light-emitting display panel may include an organic light-emitting material, and an emissive layer of the inorganic light-emitting display panel may include an inorganic light-emitting material. An emissive layer of the quantum-dot light-emitting display panel may include quantum dots and quantum rods. Hereinafter, it will be exemplified that the display panel DP is an organic light-emitting display panel.

The display panel DP may include a plurality of pixels. Each of the pixels may include at least one transistor and a light-emitting element. FIG. 12 illustrates a region in which one transistor T1 and a light-emitting element OL of one of the pixels of the display panel DP are disposed. Referring to FIG. 12, the display panel DP may include a base layer BL, a circuit element layer DP-CL, a display element layer DP-OL, and an encapsulation layer TFL.

The base layer BL may provide a base surface on which the circuit element layer DP-CL is disposed. The base layer BL may include a synthetic resin layer. The synthetic resin layer may be formed on a support substrate that is used in manufacture of the display panel DP, and then a conductive layer and an insulating layer may be formed on the synthetic resin layer. Thereafter, the support substrate may be removed, and the synthetic resin layer from which the support substrate is removed may correspond to the base layer BL.

At least one inorganic layer may be disposed on an upper surface of the base layer BL. The inorganic layer may constitute a barrier layer and/or a buffer layer. FIG. 12 illustrates a buffer layer BFL disposed on the base layer BL. The buffer layer BFL may improve a coupling force between the base layer BL and a semiconductor pattern of the circuit element layer DP-CL.

The circuit element layer DP-CL may be disposed on the buffer layer BFL. The circuit element layer DP-CL may include at least one insulating layer and a circuit element. The circuit element may include a signal line and a pixel drive circuit. The circuit element layer DP-CL may be formed through a process of forming an insulating layer, a semiconductor layer, and a conductive layer by coating, deposition, or the like and a process of making the insulating layer, the semiconductor layer, and the conductive layer subject to patterning by a photolithography process.

In this embodiment, the circuit element layer DP-CL may include the transistor T1, a connecting signal line SCL, connecting electrodes CNE1 and CNE2, and a plurality of insulating layers 10 to 60. The plurality of insulating layers 10 to 60 may include the first to sixth insulating layers 10 to 60 sequentially stacked on the buffer layer BFL. Each of the first to sixth insulating layers 10 to 60 may include one of an inorganic layer and an organic layer.

The transistor T1 may include a semiconductor pattern including a source region Sa, an active region Aa, and a drain region Da, and a gate electrode Ga. The semiconductor pattern of the transistor T1 may include poly silicon. However, without being limited thereto, the semiconductor pattern may include amorphous silicon or metal oxide.

The semiconductor pattern may be divided into a plurality of regions depending on conductivities. In an embodiment, the semiconductor pattern may have different electrical properties depending on whether doping is performed or whether metal oxide is reduced, for example. A high-conductivity region in the semiconductor pattern may serve as an electrode or a signal line and may correspond to the source region Sa and the drain region Da of the transistor T1. A non-doped or non-reduced region having relatively low conductivity may correspond to the active region Aa (or, the channel region) of the transistor T1.

The connecting signal line SCL may be formed from the semiconductor pattern and may be disposed in the same layer as the source region Sa, the active region Aa, and the drain region Da of the transistor T1. In an embodiment, the connecting signal line CSL may be electrically connected to the drain region Da of the transistor T1 in a plan view.

The first insulating layer 10 may cover the semiconductor pattern of the circuit element layer DP-CL. The gate electrode Ga may be disposed on the first insulating layer 10. The gate electrode Ga may overlap the active region Aa. The gate electrode Ga may function as a mask in a process of doping the semiconductor pattern. An upper electrode UE may be disposed on the second insulating layer 20. The upper electrode UE may overlap the gate electrode Ga.

The first connecting electrode CNE1 and the second connecting electrode CNE2 may be disposed between the transistor T1 and the light-emitting element OL and may electrically connect the transistor T1 and the light-emitting element OL. The first connecting electrode CNE1 may be disposed on the third insulating layer 30 and may be connected to the connecting signal line SCL through a contact hole CNT-1 penetrating the first to third insulating layers 10 to 30. The second connecting electrode CNE2 may be disposed on the fifth insulating layer 50 and may be connected to the first connecting electrode CNE1 through a contact hole CNT-2 penetrating the fourth and fifth insulating layers 40 and 50.

The display element layer DP-OL may be disposed on the circuit element layer DP-CL. The display element layer DP-OL may include the light-emitting element OL and a pixel defining layer PDL. The light-emitting element OL may include a first electrode AE, a hole control layer HCL, an emissive pattern EML, an electron control layer ECL, and a second electrode CE.

The first electrode AE and the pixel defining layer PDL may be disposed on the sixth insulating layer 60. The first electrode AE may be connected to the second connecting electrode CNE2 through a contact hole CNT-3 penetrating the sixth insulating layer 60. The pixel defining layer PDL may have a light-emitting opening OP-PX defined therein through which at least a portion of the first electrode AE is exposed, and the portion of the first electrode AE exposed through the light-emitting opening OP-PX may correspond to an emissive region PXA. A non-emissive region NPXA may surround the emissive region PXA.

The hole control layer HCL and the electron control layer ECL may be commonly disposed in the emissive region PXA and the non-emissive region NPXA. The emissive pattern EML may be provided in a pattern form to correspond to the light-emitting opening OP-PX. The emissive pattern EML provided in the pattern form may be formed through the deposition apparatus EA (refer to FIG. 1) including the mask assembly MSA (refer to FIG. 2) in the embodiment of the disclosure.

Accordingly, the deposition substrate BS described with reference to FIG. 1 may be a working substrate provided in a state in which components disposed under the emissive pattern EML in the display panel DP are formed.

Compared to the hole control layer HCL and the electron control layer ECL that have a film form, the emissive pattern EML may be deposited in a different way. The hole control layer HCL and the electron control layer ECL may be commonly formed for the pixels by an open mask. The emissive pattern EML may be separately formed for each light-emitting element OL by the deposition openings M-OP of the mask MS described with reference to FIG. 3.

The encapsulation layer TFL may include a plurality of thin films. The encapsulation layer TFL of an embodiment may include first to third thin films EN1, EN2, and EN3 sequentially stacked one above another. Each of the first to third thin films EN1, EN2, and EN3 may include one of an inorganic film and an organic film. The inorganic film may protect the light-emitting element OL from moisture and/or oxygen. The organic film may protect the light-emitting element OL from foreign matter such as dust particles. However, a configuration of the encapsulation layer TFL is not limited to that illustrated in the drawing as long as the encapsulation layer TFL is capable of protecting the light-emitting element OL or improving light emission efficiency.

As described above, the mask assembly according to the disclosure may include the mask and the open sheet capable of minimizing tensile deformation and deformation caused by heat generated in the deposition process, and thus deposition precision in the deposition process may be improved.

While the disclosure has been described with reference to embodiments thereof, it will be apparent to those of ordinary skill in the art that various changes and modifications may be made thereto without departing from the spirit and scope of the disclosure as set forth in the following claims.

What is claimed is:

1. A mask assembly comprising:
a frame including:
a first lateral part and a second lateral part extending in a first direction and spaced apart from each other in a second direction crossing the first direction; and
a third lateral part and a fourth lateral part extending in the second direction and spaced apart from each other in the first direction, the third lateral part and the fourth lateral part being connected with the first lateral part and the second lateral part and defining a frame opening;
an open sheet including:
a body part in which a plurality of sheet openings arranged in the first direction and the second direction and overlapping the frame opening is defined; and
a connecting part protruding from the body part and at least partially overlap the frame, the connecting part including:
a first connecting part overlapping the first lateral part;
a second connecting part overlapping the second lateral part;
third connecting parts overlapping at least a portion of the third lateral part; and
fourth connecting parts overlapping at least a portion of the fourth lateral part; and
masks, each including:
a deposition part in which deposition openings overlapping a corresponding sheet opening among the plurality of sheet openings are defined; and
coupling parts protruding from the deposition part and spaced apart from each other with the deposition part therebetween.

2. The mask assembly of claim 1, wherein the third connecting parts are spaced apart from each other in the second direction,
wherein the fourth connecting parts are spaced apart from each other in the second direction, and
wherein the third connecting parts and the fourth connecting parts do not overlap the plurality of sheet openings when viewed in the first direction and the second direction.

3. The mask assembly of claim 2, wherein a first portion of the body part adjacent to the third lateral part is spaced apart from the third lateral part by a predetermined gap, and
wherein a second portion of the body part adjacent to the fourth lateral part is spaced apart from the fourth lateral part by a predetermined gap.

4. The mask assembly of claim 3, wherein one portion of each of the third connecting parts overlaps the frame opening, and a remaining portion of each of the third connecting parts overlaps the third lateral part, and
Wherein one portion of each of the fourth connecting parts overlaps the frame opening, and a remaining portion of each of the fourth connecting parts overlaps the fourth lateral part.

5. The mask assembly of claim 4, further comprising:
first welding protrusions formed on the remaining portion of each of the third connecting parts; and
second welding protrusions formed on the remaining portion of each of the fourth connecting parts.

6. The mask assembly of claim 3, wherein two third connecting parts adjacent to each other among the third connecting parts, the third lateral part, and the first portion of the body part define an empty space extending in the second direction in a plan view, and
wherein two fourth connecting parts adjacent to each other among the fourth connecting parts, the fourth lateral part, and the second portion of the body part define an empty space extending in the second direction in the plan view.

7. The mask assembly of claim 1, wherein the first connecting part extends in the first direction and entirely overlaps the first lateral part, and
wherein the second connecting part extends in the first direction and entirely overlaps the second lateral part.

8. The mask assembly of claim 7, wherein each of the coupling parts extends in the first direction.

9. The mask assembly of claim 7, further comprising:
welding protrusions formed on the first connecting part and the second connecting part.

10. The mask assembly of claim 1, wherein widths of the first lateral part and the second lateral part in the first direction are greater than widths of the third lateral part and the fourth lateral part in the second direction.

11. The mask assembly of claim 1, wherein widths of the first lateral part and the second lateral part in the first direction are smaller than widths of the third lateral part and the fourth lateral part in the second direction.

12. The mask assembly of claim 1, wherein the frame, the open sheet, and the masks include one of invar and stainless steel.

13. The mask assembly of claim 1, wherein each of the first connecting part and the second connecting part, when viewed in the second direction, overlaps sheet openings arranged in the first direction among the plurality of sheet openings.

14. The mask assembly of claim 1, wherein each of the masks has a thickness of about 10 micrometers to about 30 micrometers.

15. The mask assembly of claim 1, wherein the open sheet has a thickness of about 50 micrometers to about 200 micrometers.

16. A mask assembly manufacturing method comprising:
providing a frame including first lateral parts extending in a first direction and second lateral parts extending in a second direction crossing the first direction and defining a frame opening with the first lateral parts;
stretching an open sheet including a body part in which sheet openings overlapping the frame opening and connecting parts protruding from the body part are defined;
coupling the connecting parts to the frame through a first welding process;
stretching a mask including:
a deposition part in which deposition openings overlapping one sheet opening among the sheet openings are defined; and
coupling parts protruding from the deposition part in the second direction and extend in the first direction; and
coupling the coupling parts to the open sheet through a second welding process,
wherein a connecting part having a relatively large area coupled with the frame among the connecting parts extends in the first direction, and
wherein the stretching the mask includes stretching the coupling parts in the second direction.

17. The mask assembly manufacturing method of claim 16, wherein each of the coupling parts includes a first portion protruding from the deposition part and a second portion protruding from the first portion, and
wherein the stretching the mask includes stretching the second portion in a direction in which the second portion protrudes.

18. The mask assembly manufacturing method of claim 17, further comprising:
removing the second portions from the mask.

19. The mask assembly manufacturing method of claim 16, wherein an arrangement direction of welding protrusions formed on the connecting part having the relatively large area coupled with the frame among the connecting parts is the same as an arrangement direction of welding protrusions formed on the coupling parts.

20. The mask assembly manufacturing method of claim 16, wherein a portion of the body part adjacent to a connecting part having a relatively small area coupled with the frame among the connecting parts is spaced apart from the frame by a predetermined gap.

21. A mask assembly comprising:
a frame including:
a first lateral part and a second lateral part extending in a first direction and spaced apart from each other in a second direction crossing the first direction; and
a third lateral part and a fourth lateral part extend in the second direction and spaced apart from each other in the first direction, the third lateral part and the fourth lateral part being connected with the first lateral part and the second lateral part and defining a frame opening;
an open sheet including:
first sticks extending in the first direction and spaced apart from each other in the second direction; and
second sticks extending in the second direction and spaced apart from each other in the first direction, the second sticks being intersecting the first sticks and defining a plurality of sheet openings; and
masks, each including:
a deposition part in which deposition openings overlapping a corresponding sheet opening among the plurality of sheet openings are defined; and
coupling parts protruding from the deposition part and spaced apart from each other with the deposition part therebetween,
wherein stick recesses are defined in a thickness direction on sticks disposed away from the frame among the first sticks and the second sticks, and portions of sticks disposed adjacent to the frame are inserted into the corresponding stick recesses.

22. The mask assembly of claim 21, wherein each of the first sticks includes first connecting portions coupled with the first lateral part and the second lateral part and a first central portion disposed between the first connecting portions and overlapping the frame opening, and
wherein each of the second sticks includes second connecting portions coupled with the third lateral part and the fourth lateral part and a second central portion disposed between the second connecting portions and intersecting the first central portions and define the plurality of sheet openings.

23. The mask assembly of claim 22, wherein widths of the first sticks in the first direction are greater than widths of the second sticks in the second direction,
wherein the first sticks are disposed farther away from the frame than the second sticks, and
wherein a first central portion of each of first sticks adjacent to the first lateral part and the second lateral part among the first sticks is coupled with the first lateral part and the second lateral part.

24. The mask assembly of claim 23, wherein each of the coupling parts is coupled to a corresponding first central portion among the first central portions.

25. The mask assembly of claim 22, wherein widths of the first sticks in the first direction are greater than widths of the second sticks in the second direction,
wherein the second sticks are disposed farther away from the frame than the first sticks, and
wherein the second central portion of each of second sticks adjacent to the third lateral part and the fourth lateral part among the second sticks is coupled with the third lateral part and the fourth lateral part.

26. The mask assembly of claim 25, wherein each of the coupling parts is coupled to a corresponding second central portion among the second central portions.
